(19) United States
(12) Patent Application Publication
(10) Pub. No.: US 2008/0260967 A1
(43) Pub. Date: Oct. 23, 2008

(54) APPARATUS AND METHOD FOR INTEGRATED SURFACE TREATMENT AND FILM DEPOSITION

(76) Inventors: Hyungsuk Alexander Yoon, San Jose, CA (US); Mikhail Korolik, San Jose, CA (US); Fritz C. Redeker, Fremont, CA (US); John M. Boyd, Woodlawn (CA); Yezdi Dordi, Palo Alto, CA (US)

Correspondence Address: MARTINE PENILLA & GENCARELLA, LLP, 710 LAKEWAY DRIVE, SUITE 200, SUNNYVALE, CA, 94085, US

(21) Appl. No.: 11/736,519

(22) Filed: Apr. 17, 2007

(51) Int. Cl. C23C 16/50; H05H 1/24

(52) U.S. Cl. 427/576; 118/722; 118/723 R; 427/250

(57) ABSTRACT

The embodiments fill the needs of systems and processes that perform substrate surface treatment to provide homogenous, clean, and sometimes activated surface in order to provide good adhesion between layers to improve metal migration and void propagation. In one exemplary embodiment, a chamber for performing surface treatment and film deposition is provided. The chamber includes a first proximity head for substrate surface treatment configured to dispense a first treatment gas to treat a portion of a surface of a substrate under the first proximity head for substrate surface treatment. The chamber also includes a first proximity head for atomic layer deposition (ALD) configured to sequentially dispensing a first reactant gas and a first purging gas to deposit a first ALD film under the second proximity head for ALD.

### CROSS REFERENCE TO RELATED APPLICATION

This application is related to U.S. patent application Ser. No. ______ (Attorney Docket No. LAM2P604), entitled “Apparatus and Method for Pre and Post Treatment of Atomic Layer Deposition,” U.S. patent application Ser. No. ______ (Attorney Docket No. LAM2P603), entitled “Apparatus and Method for Atomic Layer Deposition,” and U.S. patent application Ser. No. ______ (Attorney Docket No. LAM2P606), entitled “Apparatus and Method for Integrated Surface Treatment and Deposition for Copper Interconnect,” all of which are filed on the same day as the instant application. The disclosure of these related applications is incorporated herein by reference in their entireties for all purposes.

This application is also related to U.S. patent application Ser. No. 11/173,729 (Attorney Docket No. LAM2P508), entitled “A Method and Apparatus for Atomic Layer Deposition (ALD) in a Proximity System” filed on Jun. 30, 2005, which is incorporated herein by reference in its entirety.

### BACKGROUND

In the fabrication of semiconductor devices such as integrated circuits, memory cells, and the like, a series of manufacturing operations are performed to define features on semiconductor wafers. The semiconductor wafers include integrated circuit devices in the form of multi-level structures defined on a silicon substrate. At a substrate level, transistor devices with diffusion regions are formed. In subsequent levels, interconnect metallization lines are patterned and electrically connected to the transistor devices to define a desired integrated circuit device. Also, patterned conductive layers are insulated from other conductive layers by dielectric materials.

Reliably producing sub-micron and smaller features is one of the key technologies for the next generation of very large scale integration (VLSI) and ultra large scale integration (ULSI) of semiconductor devices. However, the shrinking dimensions of interconnect in VLSI and ULSI technologies have placed additional demands on the processing capabilities. As circuit densities increase, the widths of vias, contacts and other features, as well as the dielectric materials between them, decrease to sub-micron dimensions (e.g., less than 0.20 micrometers or less), whereas the thickness of the dielectric layers remains substantially constant, with the result that the aspect ratios for the features, i.e., their height divided by width, increase. Many traditional deposition processes have difficulty achieving substantially void-free and seam-free filling of sub-micron structures where the aspect ratio exceeds 4:1.

Currently, copper and its alloys have become the metals of choice for sub-micron interconnect technology due to its lower resistivity. One problem with the use of copper is that copper diffuses into silicon, silicon dioxide, and other dielectric materials, which may compromise the integrity of devices. Therefore, conformal barrier layers become increasingly important to prevent copper diffusion. Copper might not adhere well to the barrier layer; therefore, a liner layer might need to be deposited between the barrier layer and copper. Conformal deposition of the liner layer is also important to provide good step coverage to assist copper adhesion and/or deposition.

Conformal deposition of the barrier layer on interconnect features by deposition methods, such as atomic layer deposition (ALD), needs to occur on clean surfaces to ensure good adhesion between the barrier layer and/or liner layer, and the material(s) the barrier layer deposited upon. Surface impurity can become a source of defects during the heating cycles of the substrate processing. Pre-treatment can be used to remove unwanted compounds from the substrate surface prior to barrier deposition. In addition, deposition by ALD might need surface pre-treatment to make the substrate surface easier to bond with the deposition precursor to improve the quality of barrier layer deposition.

Electro-migration (EM) is a well-known reliability problem for metal interconnects, caused by electrons pushing and moving metal atoms in the direction of current flow at a rate determined by the current density. EM in copper lines is a surface phenomenon. It can occur wherever the copper is free to move, typically at an interface where there is poor adhesion between the copper and another material, such as at the copper/barrier or copper/liner interface. The quality and conformality of the barrier layer and/or liner layer can certainly affect the EM performance of copper interconnect. It is desirable to perform the ALD barrier and liner layer deposition right after the surface pre-treatment, since the pre-treated surface might be altered if the surface is exposed to oxygen or other contaminants for a period of time.

A post-treatment after barrier and/or liner layer deposition prior to the deposition of copper can improve the adhesion between the barrier or liner layer with copper by removing impurities from the substrate surface. In addition, a post-treatment after barrier or liner layer deposition prior the deposition of a copper seed layer by electroless method can increase nucleation sites for copper seed layer deposition, which can improve the film quality of the copper seed layer.

In view of the foregoing, there is a need for apparatus and methods that perform substrate surface treatment and ALD deposition to deposit conformal and high-quality barrier layer and/or liner layers for copper interconnect to improve metal migration performance and to reduce void propagation.

### SUMMARY

Broadly speaking, the embodiments fill the needs of integrated apparatus and methods that perform substrate surface treatment and ALD deposition in one chamber to deposit conformal and high-quality barrier layer and/or liner layers for copper interconnect with improved metal migration performance and reduced void propagation. It should be appreciated that the present invention can be implemented in numerous ways, including as a solution, a method, a process, an apparatus, or a system. Several inventive embodiments of the present invention are described below.

In one embodiment, a chamber for performing surface treatment and film deposition is provided. The chamber includes a first proximity head for substrate surface treatment configured to dispense a first treatment gas to treat a portion of a surface of a substrate under the first proximity head for substrate surface treatment. The chamber also includes a first proximity head for atomic layer deposition (ALD) configured to sequentially dispensing a first reactant gas and a first purging gas to deposit a first ALD film under the second proximity head for ALD.

In another embodiment, a method of performing surface treatment and film deposition on a substrate in a processing chamber is provided. The method includes placing the substrate in the processing chamber with a plurality of proximity heads for surface treatment and film deposition. Each of the plurality of proximity head covers a portion of a substrate surface. The method also includes moving a pre-treatment proximity head above a region on the substrate surface. The method further includes performing a surface pre-treatment with the pre-treatment proximity head at the region on the substrate surface. In addition, the method includes moving an atomic layer deposition 1 (ALD1) proximity head above the region on the substrate surface. Additionally, the method includes depositing a barrier layer for copper with the ALD 1 proximity head at the region on the substrate surface.

Other aspects and advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings, and like reference numerals designate like structural elements.

FIG. 1A show an exemplary cross section of an interconnect structure prior to barrier layer deposition, in accordance of an embodiment of the current invention.

FIG. 1B show an exemplary cross section of an interconnect structure after deposition of barrier layer deposition and copper, in accordance of an embodiment of the current invention.

FIG. 2 shows an exemplary ALD deposition cycle.

FIG. 3 shows a cross-sectional diagram of an ALD film grown with limited growth sites in the beginning of ALD deposition.

FIG. 4A shows a schematic diagram of a proximity head ALD chamber, in accordance with an embodiment of the current invention.

FIG. 4B shows a schematic diagram of a proximity head for ALD, in accordance with an embodiment of the current invention.

FIG. 4C shows a schematic diagram of a proximity head for ALD coupled to an RF power source over a substrate and a grounded substrate support, in accordance with an embodiment of the current invention.

FIG. 4D shows a bottom view of a proximity head for ALD, in accordance with an embodiment of the current invention.

FIG. 4E shows a schematic cross-sectional view of a proximity head for ALD below a substrate, in accordance with one embodiment of the current invention.

FIG. 4F shows a schematic diagram of a thin film deposited by proximity head ALD, in accordance with an embodiment of the current invention.

FIG. 5A shows a schematic diagram of a chamber with a surface treatment proximity head, in accordance with an embodiment of the current invention.

FIG. 5B shows a schematic diagram of a proximity head for surface treatment, in accordance with an embodiment of the current invention.

FIG. 6A show s plurality of proximity heads for surface treatment and deposition over a substrate, in accordance with an embodiment of the current invention.

FIG. 6B show s plurality of proximity heads for surface treatment and deposition over a substrate, in accordance with another embodiment of the current invention.

FIG. 7A shows a interconnect feature deposited with an ALD barrier layer, an ALD liner layer, and a CVD layer, in accordance with one embodiment of the current invention.

FIG. 7B shows a proximity head for CVD over a substrate, in accordance with one embodiment of the current invention.

FIG. 7C show s plurality of proximity heads for surface treatment and deposition over a substrate, in accordance with yet another embodiment of the current invention.

FIG. 8A shows a process flow of surface treatment and deposition using a plurality of proximity heads in a process chamber, in accordance with an embodiment of the current invention.

FIG. 8B shows a process flow of surface treatment and deposition using a plurality of proximity heads in a process chamber, in accordance with another embodiment of the current invention.

### DETAILED DESCRIPTION OF THE EXEMPLARY EMBODIMENTS

Several exemplary embodiments for apparatus and methods for substrate surface treatment prior to and after deposition are detailed. Substrate pre-treatment prior to film deposition can remove surface contaminants and/or activate surface for deposition. Substrate post-treatment after film deposition can remove surface contaminants and/or can prepare the substrate surface for deposition of another film. The pre-treatment and post-treatment are performed with proximity heads, which can be integrated in one processing chamber. In addition, pre-treatment and post-treatment using proximity heads can also be integrated with one or more atomic layer deposition (ALD) proximity heads to complete the deposition of barrier layer and/or liner layer and surface treatment in one chamber.

It should be appreciated that the present invention can be implemented in numerous ways, including a process, a method, an apparatus, or a system. Several inventive embodiments of the present invention are described below. It will be apparent to those skilled in the art that the present invention may be practiced without some or all of the specific details set forth herein.

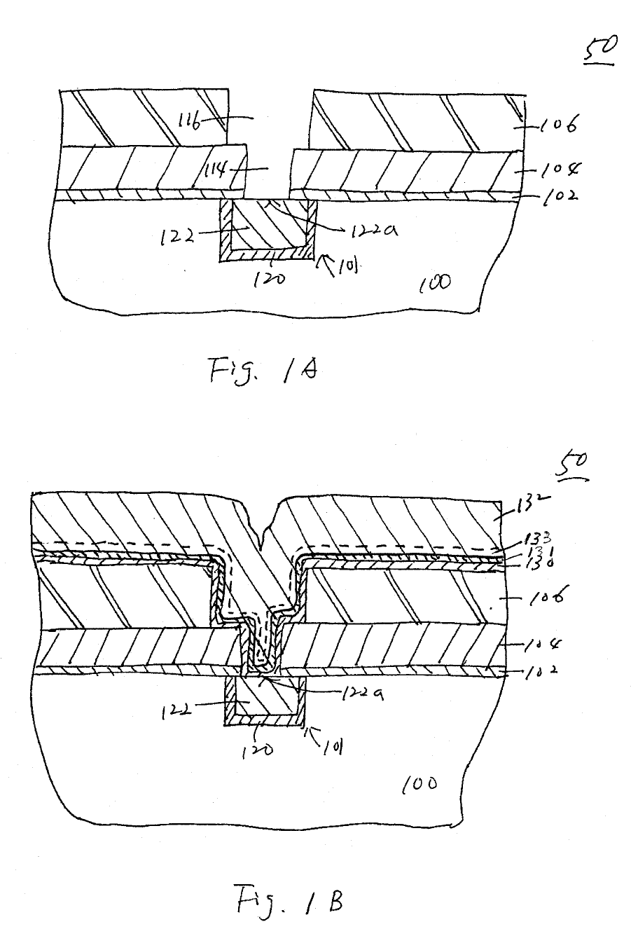

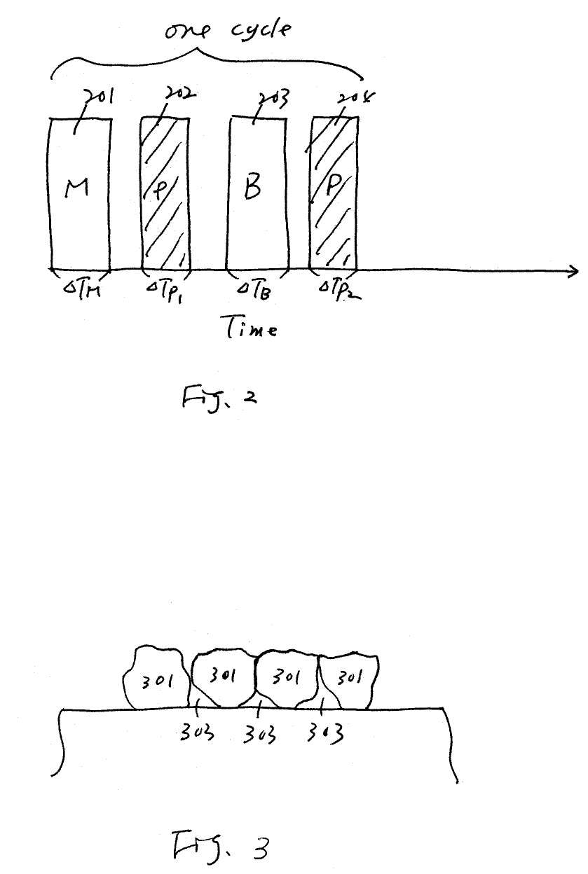

FIG. 1A shows an exemplary cross-section of an interconnect structure(s) after being patterned by using a dual damascene process sequence. The interconnect structure(s) is on a substrate 50 and has a dielectric layer 100, which was previously fabricated to form a metallization line 101 therein. The metallization line is typically fabricated by etching a trench into the dielectric 100 and then filling the trench with a conductive material, such as copper.

In the trench, there is a barrier layer 120, used to prevent the copper material 122, from diffusing into the dielectric 100. The barrier layer 120 can be made of PVD tantalum nitride (TaN), PVD tantalum (Ta), ALD TaN, or a combination of these films. Other barrier layer materials can also be used. Alternatively, a liner layer can be deposited between the barrier layer 120 and the copper material 122 to increase the adhesion between the copper material 122 and the barrier layer 120. Another barrier layer 102 is deposited over the planarized copper material 122 to protect the copper material 122 from premature oxidation when via holes 114 are etched through overlying dielectric materials 104, 106 to the barrier layer 102. The barrier layer 102 is also configured to function as a selective etch stop and a copper diffusion barrier. Exemplary barrier layer 102 materials include silicon nitride (SiN) or silicon carbide (SiC).

A via dielectric layer 104 is deposited over the barrier layer 102. The via dielectric layer 104 can be made of a material with a low dielectric constant. Over the via dielectric layer 104 is a trench dielectric layer 106. The trench dielectric layer 106 may be a low K dielectric material, which can be a material same as or different from layer 104. In one embodiment, both the via and trench dielectric layers are made of the same material, and deposited at the same time to form a continuous film. After the trench dielectric layer 106 is deposited, the substrate 50 that holds the structure(s) undergoes patterning and etching processes to form the via holes 114 and trenches 116 by known art.

FIG. 1B shows that after the formation of via holes 114 and trenches 116, a barrier layer 130, an optional liner layer 131, and a copper layer 132 are deposited to line and fill the via holes 114 and the trenches 116. The barrier layer 130 can be made materials, such as tantalum nitride (TaN), tantalum (Ta), Ruthenium (Ru), or a hybrid combination of these films. Barrier layer materials may be other refractory metal compound including but not limited to titanium (Ti), titanium nitride (TiN), tungsten (W), zirconium (Zr), hafnium (Hf), molybdenum (Mo), niobium (Nb), vanadium (V), and chromium (Cr), among others.

The optional liner layer 131 can be made materials, such as tantalum (Ta), and Ruthenium (Ru). Liner layer materials may be other refractory metal compound including but not limited to titanium (Ti), titanium nitride (TiN), tungsten (W), zirconium (Zr), hafnium (Hf), molybdenum (Mo), niobium (Nb), vanadium (V), and chromium (Cr), among others. While these are the commonly considered materials, other barrier layer and liner layer materials can also be used. A copper film 132 is then deposited to fill the via holes 114 and the trenches 116. A copper seed layer 133 can be deposited prior to the gap-filling copper film 132 is deposited.

As discussed above, before depositing a metallic barrier layer 130, the substrate surface can have residual contaminants left from etching the dielectric layers 104, 106 and the barrier layer 102 to allow the metallic barrier layer 130 to be in contact with the copper material 122. A cleaning process, such as Ar sputtering, can be used to remove surface contaminant. Also as discussed above, conformal deposition of metallic barrier layer 130 by ALD might need surface pre-treatment to make the substrate surface easier to bond with the deposition precursor. The reason is described below.

Atomic layer deposition (ALD) is known to produce thin film with good step coverage. ALD is typically accomplished by using multiple pulses, such as two pulses, of reactants with gas purge in between, as shown in FIG. 2. For metallic barrier deposition, a pulse of barrier-metal-containing reactant (M) 201 is delivered to the substrate surface, followed by a pulse of purging gas (P) 202. The pulse of barrier-metal-containing reactant 201 delivered to the substrate surface to form a monolayer of barrier metal, such as Ta, on the substrate surface. In one embodiment, the pulse of purging gas is a plasma-enhanced (or plasma-assisted) gas. The barrier metal, such as Ta, bonds to the substrate surface, which can be made of a dielectric material, such as low-k materials 104, 106 of FIG. 1A, and/or a conductive material, such as copper material 122 of FIG. 1A. The purge gas 202 removes the excess barrier-metal-containing reactant 201 from the substrate surface.

Following the pulse of the purging gas 202, a pulse of reactant (B) 203 is delivered to the substrate surface. If the barrier material contains nitrogen, such as TaN, the reactant (B) 203 is likely to contain nitrogen. The reactant (B) 203 can be nitrogen-containing gas to form TaN with the Ta on the substrate. Examples of reactant (B) 203 include ammonia (NH₃), N₂, and NO. Other N-containing precursors gases may be used including but not limited to NₓH_{y} for x and y integers (e.g., N₂H₄), N₂ plasma source, NH₂N(CH₃)₂, among others. If the barrier material contains little or no nitrogen, the reactant (B) 203 can be a hydrogen-containing reducing gas, such as H₂. H₂ is a reducing gas that reacts with the ligand bounding with the barrier-metal in reactant M 201 to terminate the film deposition. Following pulse 203 is a pulse of purging gas 204. Reactants M, B, and purge gas P can be plasma enhanced or thermally excited. In one embodiment, the pulse of reactant (B) 203 is a plasma-enhanced (or plasma-assisted).

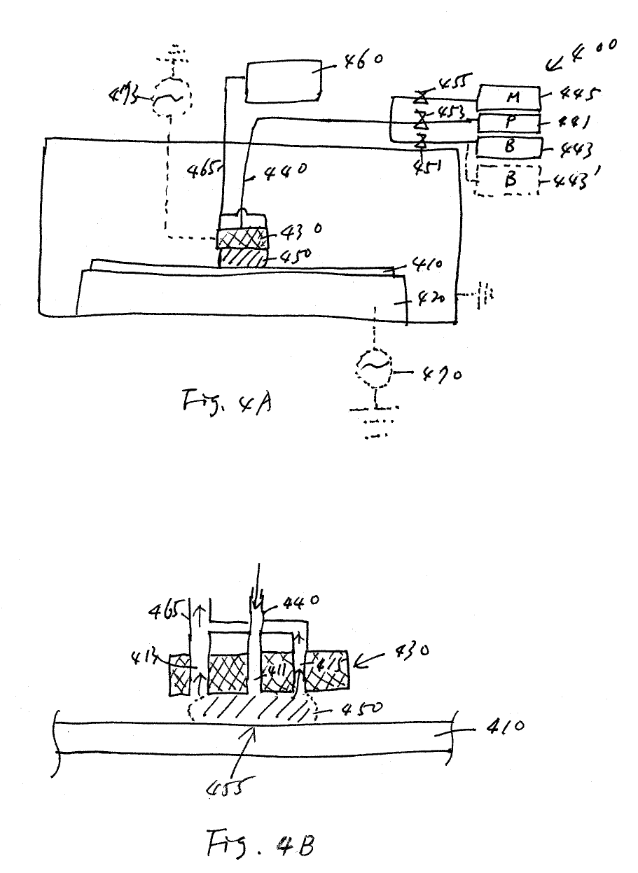

However, in some situations, the substrate surface does not possess ample bonding sites for all the potential locations on the surface. Accordingly, the barrier-metal-containing reactant M (or precursor) bonding to the surface can result in the formation of islands and grains which are sufficiently far apart to form poor quality ALD film. FIG. 3 shows an ALD film with islands 301 that are grown with limited growth sites in the beginning of ALD deposition. Between the islands 301, there are voids 303 along the surface of the substrate. Substrate surface, such as SiO2 or low-k material, can be quite inert and not easy to bond with for barrier metal in the barrier-metal-containing reactant M. Surface treatment by OH, O, or O radical exposure can efficiently insert HOH into the SiOSi to generate 2 Si—OH surface species that are highly reactive with the barrier-metal-containing reactant M. The introduction of the pre-treatment plasma into the processing chamber containing the substrate can result in the formation of surface species at various desired bonding sites. In order to grow continuous interfaces and films, one embodiment of the present invention is to pre-treat the surface of the substrate prior to ALD in order to make the surface more susceptible to ALD, due to more deposition sites.

Due to the relatively long deposition cycle of conventional ALD process, the deposition rate (or throughput) for some barrier or liner layers, such as Ru, is considered too low from manufacturing standpoint. In order to improve the deposition rate, new systems and methods of using a proximity head for ALD of barrier layer and/or liner layer are invented. Details of using a proximity head to deposit an ALD film are described in commonly assigned U.S. patent application Ser. No. ______ (Attorney Docket No. LAM2P603), entitled “Apparatus and Method for Atomic Layer Deposition,” which is filed on the same day as the instant application. This application is incorporated herein by reference in its entirety. The ALD proximity head is briefly introduced below.

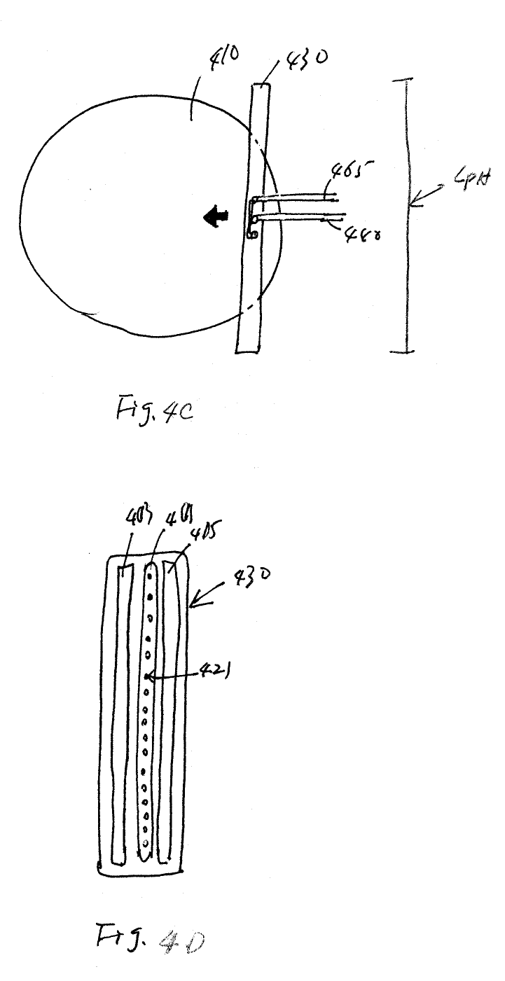

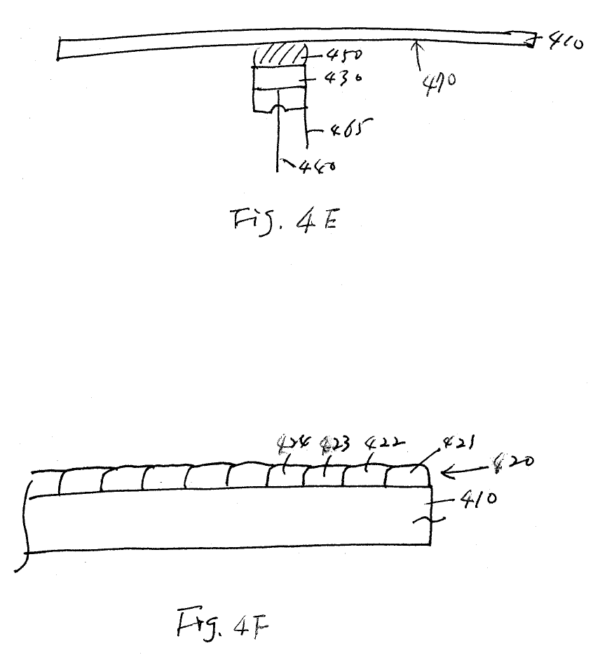

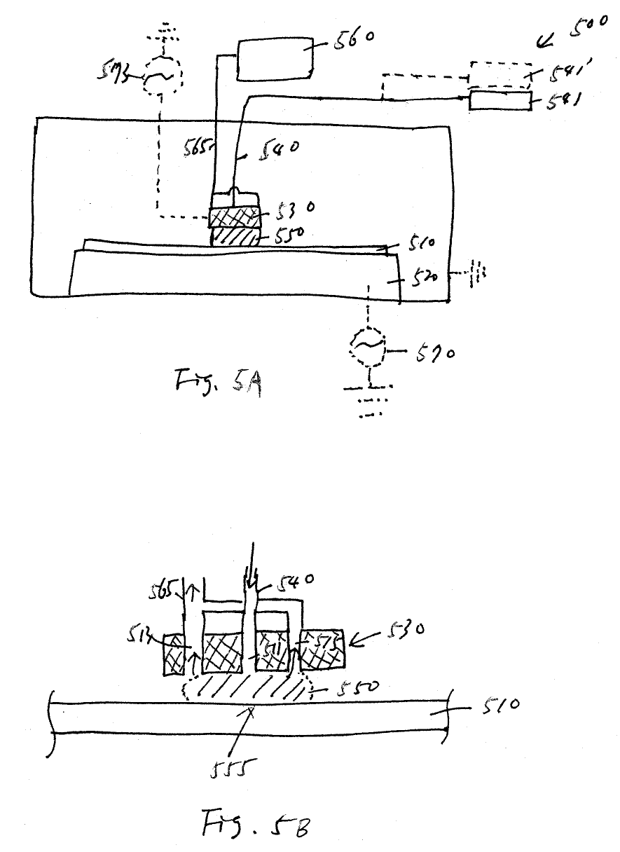

FIG. 4A shows a schematic diagram of an ALD reactor 400 with a proximity head 440. In reactor 400, there is a substrate 410 disposed on a substrate support 420. The proximity head 440 is supported above substrate 410 and covers only a portion of substrate surface. Between the proximity head 430 and the substrate 410, there is a reaction volume 450.

A gas inlet 440 and a vacuum line 465 are coupled to the proximity head 430. The gas inlet 440 supplies reactants and purging gas to process chamber 400. The gas inlet 440 can be coupled to a plurality of containers that store reactants and purging gas. The gas inlet 440 can be coupled to a container 441 that stores a first reactant, such as reactant M described in FIG. 2. The gas inlet 440 can also be coupled to a container 443 that supplies a second reactant, such as reactant B described in FIG. 2. As described above, reactant B can be plasma assisted. Reactant B can be supplied by a reactor 443′ that generate plasmarized reactant B. Alternatively, the substrate support 420 can be coupled to a radio frequency (RF) generator to generate a plasma of reactant B when reactant B is dispensed into the reaction volume 450, instead of supplying plasmarized reactant B from reactor 443′. Another alternative is to couple an RF generator 473 to the proximity head 430 to generate plasma. In one embodiment, one electrode is coupled to the RF generator and the other electrode is grounded, during plasma generation.

The gas inlet 440 is coupled to a container 445 that stores a purging gas. Reactant M, purging gas and reactant B can be diluted by a carrier gas, which can be an inert gas. During ALD deposition cycles, one of reactants M, B and purging gas P is supplied to the gas inlet 440. The on and off of gas supplies of these gas are controlled by valves 451, 453, and 455. The other end of the vacuum line 465 is a vacuum pump 460. The reaction volume 450 in FIG. 4a is much smaller than the reaction volume in a conventional ALD chamber. The deposition rate of proximity head ALD of barrier layer can be 10 times or higher than the deposition rate of conventional ALD.

FIG. 4B shows one embodiment of a proximity head 410 disposed above substrate 410, with a reaction volume 450 between the proximity head 410 and substrate 410. The substrate surface under the reaction volume 450 is an active process region 455. The proximity head 410 has one or more gas channels 411 that supplies reactant M, B, or purging gas P. On both sides of the gas channel 411, there are vacuum channels 413, 415 pumping excessive reactant M, B, purging gas, and/or reactant byproducts from the reaction volume 450. Reactant M, B, and purging gas P is passed through the gas channel 411 sequentially, such as the sequence shown in FIG. 2. Gas channel 411 is coupled to the gas inlet 440. When a pulse of gas, either reactant M, B, or P, is injected form the gas channel 411 to the substrate surface, the excess amount of gas is pumped away from the substrate surface by the vacuum channels 413, 415, which keeps the reaction volume small and reduces the purging or pumping time. Since the reaction volume is small, only small amount of reactant is needed to cover the small reaction volume. Similarly only small amount of purging gas is needed to purge the excess reactant from the reaction volume 450. In addition, the vacuum channels are right near the small reaction volume 450, which assists the pumping and purging of the excess reactants, purging gas, and reaction byproducts from the substrate surface. As a consequence, the pulse times ΔT_{M}, ΔT_{B}, ΔT_{P1}, and ΔT_{P2} for reactants M, B, and purging gas respectively, can be greatly reduced.

As a consequence, the ALD cycle time can be reduced and the throughput can be increased. Details of why ALD by proximity head has higher throughput than conventional ALD are discussed commonly assigned U.S. patent application Ser. No. ______ (Attorney Docket No. LAM2P603), entitled “Apparatus and Method for Atomic Layer Deposition,” which is mentioned above.

The proximity head for ALD can also have multiple sides with different sides dispensing different types of processing gases. Rotating the proximity head from side to side allows the ALD cycle to be completed and a thin film being deposited.

FIG. 4C shows a schematic top view of an embodiment of proximity head 430 of FIGS. 4A and 4B on top of a substrate 410. Proximity head 430 moves across the substrate surface. In this embodiment, the length of the proximity head L_{PH} is equal to or greater than the diameter of the substrate. The reaction volume under the proximity covers the substrate surface underneath. By moving the proximity head across the substrate once, the entire substrate surface is deposited with a thin film of the barrier or liner layer. In another embodiment, the substrate 410 is moved under the proximity head 430. In yet another embodiment, both the proximity head 430 and the substrate 410 move, but in opposite directions to cross each other. The thickness of the thin film deposited can be controlled by the speed the proximity head 430 move across the substrate 410.

FIG. 4D shows an embodiment of a bottom view of the proximity head 430 of FIGS. 3A and 3B. The proximity head 430 has a gas injection head 401, coupled to gas channel 411 with a plurality of gas injection holes 421. The arrangement and shapes of gas injection holes 421 shown in FIG. 4D are merely examples. Other arrangement of injection holes and shapes of injection holes can also be used.

In addition to placing a substrate under a proximity head, a substrate can also be placed above a proximity head to treat the substrate surface. FIG. 4E shows a schematic drawing of a proximity head 430 placed below a substrate 410. The substrate 410 is suspended above the proximity head 430 by a device (not shown). The proximity head 430 is also supported by a mechanical device (not shown).

FIG. 4F shows a schematic cross-sectional diagram of a thin barrier or liner layer 420 deposited on a substrate 410. At the edge of substrate 410, a small section 421 of thin barrier or liner layer 420 is deposited under the proximity head. After section 421 is deposited, the proximity is moved towards left to deposit another section 422, which overlaps section 421 slightly. Section 423 follows section 422, and section 424 follows section 423, and so on. At the other edge of the substrate, the deposition process stops and a complete thin film 410 is formed.

As discussed above, in order to grow continuous interfaces and films, one embodiment of the present invention is to pre-treat the surface of the substrate prior to ALD in order to have the surface more susceptible to ALD. In addition, after barrier layer and/or liner layer is deposited on the substrate surface, the surface can be post-treated to remove any surface contaminant or to reduce impurities in the film, or to density the film. Post-treatment can also enhance nucleation of copper seed layer deposited by an electroless process in a similar mechanism described above for pre-treatment prior to barrier layer deposition. Copper seed layer with enhanced nucleation has better film quality and results in better reliability (such as EM performance) and avoids delamination and void propagation. Surface pre-treatment and post-treatment can be performed by proximity heads. Details of using proximity heads for surface treatment are described in commonly assigned U.S. patent application Ser. No. ______ (Attorney Docket No. LAM2P604), entitled “Apparatus and Method for Pre and Post Treatment of Atomic Layer Deposition,” which is filed on the same day as the instant application. This application is incorporated herein by reference in its entirety. Surface treatment using proximity is briefly introduced below.

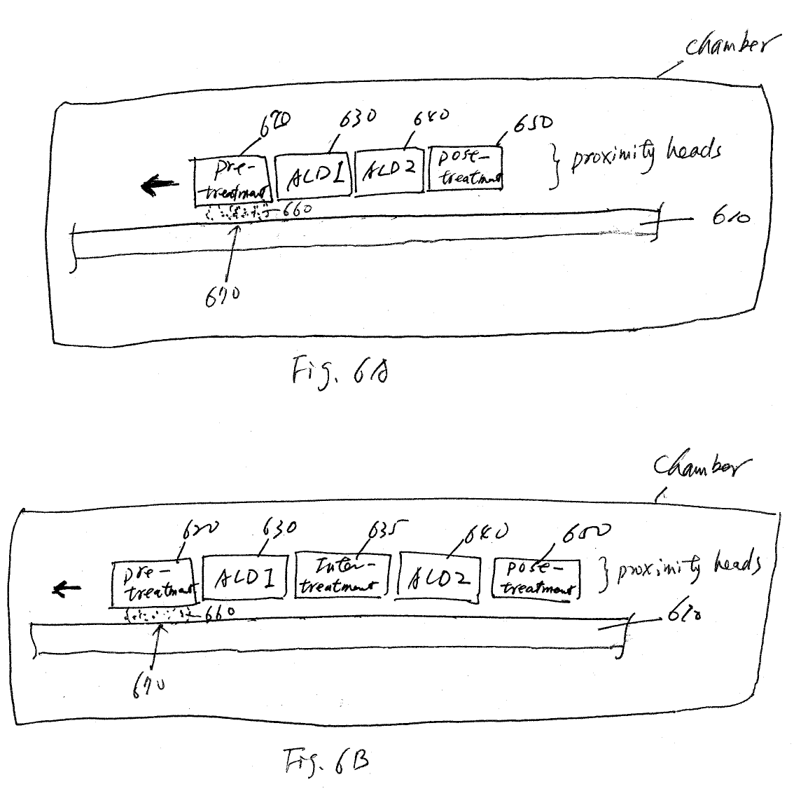

FIG. 5A shows a schematic diagram of a chamber 500 for substrate surface treatment with a proximity head 530. In chamber 500, there is a substrate 510 disposed on a substrate support 520. The proximity head 530 is supported above substrate 510. Between the proximity head 530 and the substrate 510, there is a reaction volume 550. Since the proximity head 530 only covers a portion of the substrate surface, the reaction volume 550 is much smaller than conventional surface treatment that applies to the entire substrate surface.

A gas inlet 540 and a vacuum line 565 are coupled to the proximity head 530. The other end of the vacuum line 565 is a pump 560. The gas inlet 540 supplies reactant gas to process chamber 500. The excess treatment gas is pumped away from the from the reaction volume 550 by the vacuum line 565. The gas inlet 540 can be coupled to a container 541 that stores a treatment gas, such as H₂. The treatment gas can be diluted with an inert gas. As described above, the treatment gas can be plasma assisted. In one embodiment, the plasmarized treatment gas is supplied by a reactor 541′ that plasmarizes the treatment gas. Alternatively, the substrate support 520 can be coupled to a radio frequency (RF) generator to generate plasma to plasmarize treatment gas when treatment gas is dispensed into the reaction volume 550, instead of supplying plasmarized treatment from reactor 541′. Another alternative is to couple an RF generator 573 to the proximity head 530 to generate plasma. The inert gas can be used to sustain chamber pressure or to sustain plasma.

FIG. 5B shows one embodiment of a proximity head 510 disposed above substrate 510, with a reaction volume 550 between the proximity head 510 and substrate 510. The substrate surface under the reaction volume 550 is an active process region 555. The proximity head 530 has one or more gas channels 511 that supply treatment gas. On both sides of the gas channel 511, there are vacuum channels 513, 515 pumping excess treatment gas(es) from the reaction volume 550. Gas channel 511 is coupled the container of the treatment gas. When treatment gas is injected form the gas channel 511 to the substrate surface, the excess amount of gas is pumped away from the substrate surface by the vacuum channels 513, 515, which limits the reaction volume to be substantially below the proximity head 530.

The processing gases for ALD by proximity head and the treatment gas for surface treatment by proximity head can be plasma-enhanced or excited by other means, such as by thermal excitation, by UV, or by laser.

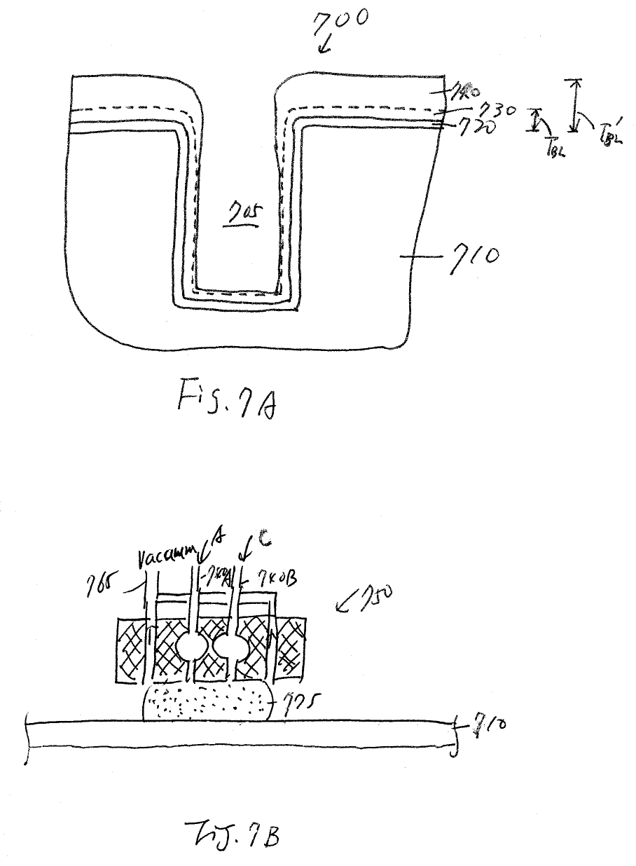

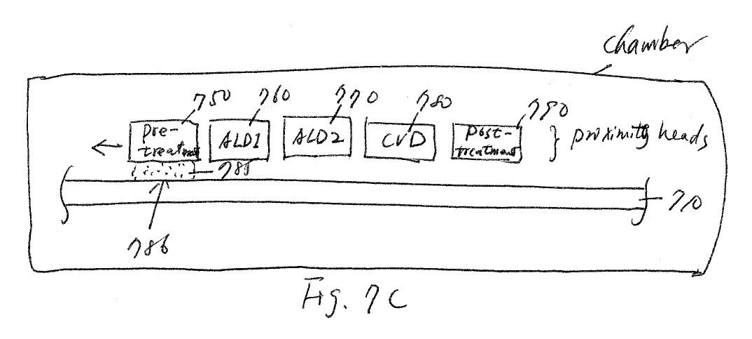

ALD proximity head(s), pre-treatment proximity head(s), and/or post-treatment proximity head(s) can be integrated in one single process chamber to complete the deposition and treatment processes. In one embodiment, for a substrate to be deposited with a thin barrier layer, such as TaN, and a liner layer, such as Ru, the substrate can be pre-treated to clean the substrate surface or the substrate surface can be pre-treated to prepare the surface for barrier layer ALD deposition, as discussed above. After barrier layer deposition and liner layer deposition, the substrate surface can be posted-treated to prepare the surface for copper seed layer deposition. In a single and integrated deposition/treatment chamber, the substrate is pre-treated, deposited with a barrier layer and a liner layer, and post-treated. FIG. 6A shows a substrate 610 with a plurality of proximity treatment and deposition heads over the substrate 610. Pre-treatment proximity head 620 is used to pre-treat the substrate surface either to remove impurities or to prepare the substrate surface for ALD. Between the proximity head 620 and the surface of substrate 610, there is a reaction volume 660. The substrate surface below the reaction volume 660 is an active process region 670. Next to pre-treatment proximity head 620 is an ALD1 proximity head 630 used to deposit a barrier layer on the substrate. After the ALD1 proximity head 630 is an ALD2 proximity head 640 used to deposit a liner layer on the substrate. After the liner layer is deposited, the substrate is post-treated either to remove impurities or to prepare the substrate surface for copper seed layer deposition following. The post-treatment is performed by a post-treatment proximity head 650. The various proximity heads move sequentially across the substrate surface to complete treatment and deposition surface. The treatment and deposition processes can occur simultaneously or in sequence.

In addition, not every proximity in the process chamber needs to be used for processing. For example, if pre-treatment is not needed for some types of substrates, the pre-treatment proximity head can move across the substrate with ALD1 proximity head, ALD2 proximity head, and post-treatment proximity, but no treatment gas is dispensed form the pre-treatment proximity head.

The embodiment shown in FIG. 6A is only an example of integrating treatment proximity head with deposition proximity head. Other combinations are possible. For example, there could be a surface treatment after the barrier layer is deposited and before the deposition of the liner layer. FIG. 6B shows an embodiment with a surface treatment between two deposition steps. Inter-treatment proximity head 635 is inserted between ALD1 proximity head 630 and ALD2 proximity head 640.

The proximity head surface treatment chamber can be integrated with other deposition, substrate cleaning, or treatment system(s) to complete copper interconnect deposition. Details of integrating an ALD chamber using a proximity head for ALD with other deposition and treatment modules can be found in commonly assigned U.S. patent application Ser. No. ______ (Attorney Docket No. LAM2P606), entitled “Apparatus and Method for Integrated Surface Treatment and Deposition for Copper Interconnect,” which is filed on the same day as the instant application. This application is incorporated herein by reference in its entirety.

The gap distance between the proximity head and the substrate for surface treatment is small is between about 5 mm to about 10 mm. The gap distance between the proximity head and the substrate during ALD changes from side to side and is less than 5 mm, such as 1 mm. The gap distance between the different proximity head and substrate surface can be different for different proximity heads in the chamber.

For copper plating, the thickness of barrier layer and/or seed layer on the substrate surface needs to be thick enough to have the sheet resistivity low enough for to copper plating. The thickness of the ALD barrier layer and/or ALD liner layer is between about 10 Å to about 50 Å, preferably between about 20 Å to about 30 Å.

FIG. 7A shows a schematic cross section of an interconnect structure 700 on a substrate 710. The interconnect structure 700 has an opening 705, and is lined with a barrier layer 720, an optional liner layer 730. The barrier layer 720 and liner layer 730 in FIG. 7A are used as examples. Alternatively, it is possible that there is only one single barrier layer 720 for copper interconnect. Both the barrier layer 720 and the liner layer 730 are deposited by ALD. Since both the barrier layer 720, and the liner 730 are deposited by ALD processes, the film thicknesses of layers 720 and 730 are quite uniform around the structure feature. The thickness of each layer is between about 10 Å to about 50 Å. The total thickness (T_{BL}) of barrier layer and liner layer is between about 20 Å to about 100 Å.

For example, the barrier layer 710 is about 20 Å of TaN barrier layer. The liner layer 730 is about 20 Å of Ru liner layer. The T_{BL} is about 40 Å with a sheet resistivity at between about 100-1000 Ω/□, which is too high for copper plating. A sheet resistivity of between about 1 Ω/□ to about 10 Ω/□ is needed for copper plating process. By adding another about 60 Å of Ru on the liner layer, the total sheet resistivity of the barrier/liner layers would be about 1 Ω/□ to about 1.5 Ω/□, and would be low enough for copper plating, without an Electroless copper seed layer. Please note that the initial step of the direct copper plating on the liner layer (or barrier layer) is referring to copper seed layer by plating. Therefore, there is a need to deposit another layer 740 over the feature to increase the total barrier/liner layer thickness T_{BL}′ over the substrate surface to lower the sheet resistivity to be between about 1 Ω/□ to about 10 Ω/□ for copper plating. In one embodiment, the total thickness T_{BL}′ is between about 60 Å to about 200 Å. Various methods can be used to deposit a barrier layer or liner layer to increase the thickness. The methods include, but not limited to, CVD and physical vapor deposition (PVD).

Proximity head can also be used to deposit a chemical vapor deposition (CVD) film. CVD film deposited by using a proximity in a fashion similar to the proximity ALD deposition allow the CVD proximity head to be integrated with surface treatment and film deposition tools using proximity heads. FIG. 7B shows a proximity head 750 that can be used to deposit a CVD film, which can be plasma-enhanced, using reactants A and C on a substrate 710. Both reactants A and C are dispensed on the substrate surface and react to form a CVD film. Excess reactants A, C, and reaction byproduct(s) Reactants A and C can be diluted by a carrier gas, can be plasma-enhanced, or can be excited by other means, described for surface treatment proximity head. Alternatively, the CVD film can be formed by decomposing one single reactant gas. In this case, either reactant A or B will be used to form the CVD film. In one embodiment, reactants A and C react to form a barrier layer or a liner layer to increase the total barrier/liner layer thickness over the substrate surface.

The CVD process using the proximity head can be conducted over a wide range of process conditions. In one embodiment, the process temperature range between about 250° C. to about 400° C. In another embodiment, the temperature range is between about 300° C. to about 350° C. In one embodiment, the process pressure is between about 1 Torr to about 10 Torr. The vacuuming of treatment gas can be performed by turbo pump capable of achieving 10⁻⁶ Torr. The gap between the substrate surface and the surface of proximity head facing the substrate is between about 1 mm to about 10 mm, in one embodiment. In another embodiment, the gap is between about 3 mm to about 7 mm.

Such a CVD proximity head can also be integrated pre-treatment proximity head(s), ALD proximity head(s), or post-treatment proximity head(s) to perform substrate surface treatment and film deposition in one single chamber. Many types of combinations are possible. Using the example in shown in FIG. 7A, a process chamber can include a pre-treatment proximity head 750, an ALD1 proximity head 760 for depositing a barrier layer, an ALD2 proximity head 770 for depositing a liner over the barrier layer, a CVD proximity head 780 for depositing another liner layer, followed by a post-treatment proximity head 790 for post-treatment, as shown in FIG. 7C.

There is a wafer area pressure (P_{wap}) in the reaction volume. For surface treatment, such as pre-clean, P_{wap} is in the range of about 100 mTorr to about 10 Torr. In another embodiment of ALD, P_{wap} is in the range between about 100 mTorr to about 2 Torr. Wafer area pressure P_{wap} in the reaction volume needs to be greater than chamber pressure (P_{chamber}) to control P_{wap}. Chamber pressure (P_{chamber}) needs to be at least slightly higher than the pressure of the vacuum pump that is used to control the chamber pressure.

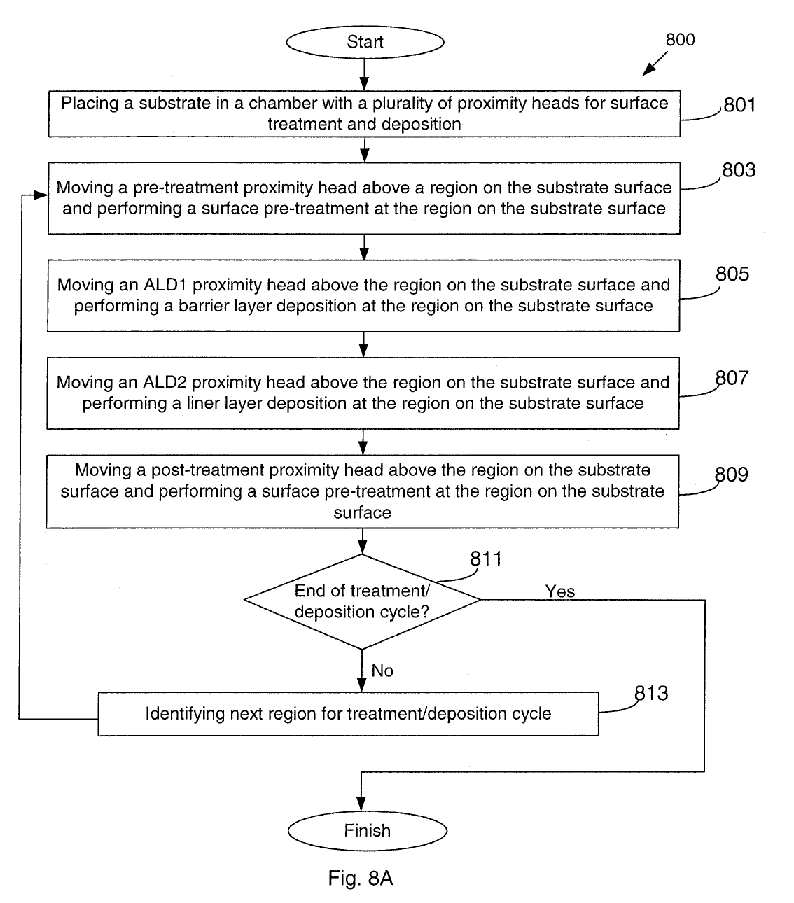

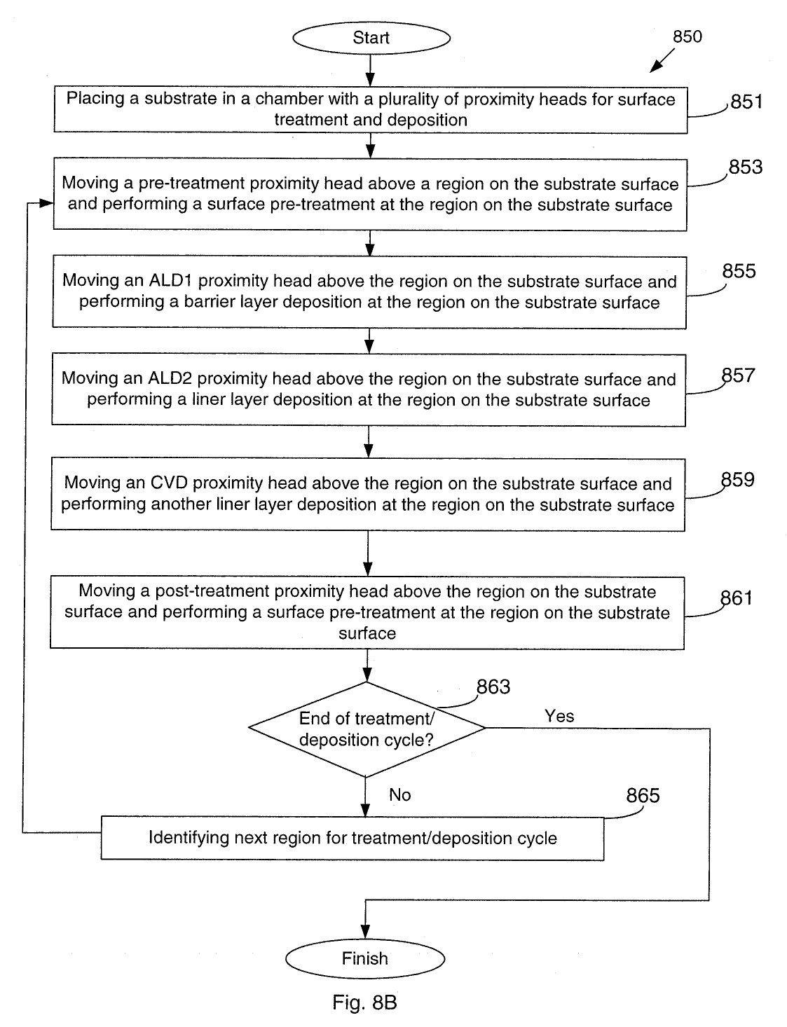

FIG. 8A shows an embodiment of a process flow 800 for pre-treating a substrate surface, depositing a barrier layer and a liner layer on the substrate surface, followed by post-treating the substrate surface in a process chamber with multiple proximity heads for treatment and deposition. At step 801, a substrate is placed in a chamber with a plurality of proximity heads for surface treatment and deposition. The plurality of proximity heads are placed in a sequence of pre-treatment proximity head, ALD1 proximity head, ALD2 proximity head, and followed by a post-treatment proximity head. At step 803, a pre-treatment proximity head is moved above a region on the substrate surface and a surface pre-treatment is performed at the region on the substrate surface. At step 805, an ALD1 proximity head is moved above a region on the substrate surface and a barrier layer is deposited at the region on the substrate surface. At step 807, an ALD2 proximity head is moved above a region on the substrate surface and a liner layer is deposited at the region on the substrate surface. At step 809, a post-treatment proximity head is moved above a region on the substrate surface and a surface post-treatment is performed at the region on the substrate surface. At step 711, a question of whether the end of deposition and surface treatment has been reached is asked. If the answer is “yes”, the deposition and surface treatment in the chamber is completed. If the answer is “no”, next region for treatment/deposition cycle is identified at step 813. Afterwards, the process cycle returns to step 803 to undergoes the pre-treatment/ALD1/ALD2/post-treatment cycle.

FIG. 8B shows an embodiment of a process flow 850 for pre-treating a substrate surface, depositing a barrier layer, a liner layer, and another liner layer on the substrate surface, followed by post-treating the substrate surface in a process chamber with multiple proximity heads for treatment and deposition, as shown in FIG. 7C. At step 851, a substrate is placed in a chamber with a plurality of proximity heads for surface treatment and deposition. The plurality of proximity heads are placed in a sequence of pre-treatment proximity head, ALD1 proximity head, ALD2 proximity head, and followed by a post-treatment proximity head. At step 853, a pre-treatment proximity head is moved above a region on the substrate surface and a surface pre-treatment is performed at the region on the substrate surface. At step 855, an ALD1 proximity head is moved above the region on the substrate surface and a barrier layer is deposited at the region on the substrate surface. At step 857, an ALD2 proximity head is moved above a region on the substrate surface and a liner layer is deposited at the region on the substrate surface.

At step 859, a CVD proximity head is moved above the region on the substrate surface and another liner layer is deposited at the region on the substrate surface. At step 861, a post-treatment proximity head is moved above the region on the substrate surface and a surface post-treatment is performed at the region on the substrate surface. At step 863, a question of whether the end of deposition and surface treatment has been reached is asked. If the answer is “yes”, the deposition and surface treatment in the chamber is completed. If the answer is “no”, next region for treatment/deposition cycle is identified at step 865. Afterwards, the process cycle returns to step 853 to undergoes the pre-treatment/ALD1/ALD2/post-treatment cycle.

The surface pre-treatment and the barrier layer deposition being performed in the same chamber reduces process time and protecting the pre-treated substrate surface from being contaminated or being non-active before the barrier layer is deposited. Surface post-treatment and the liner layer deposition being performed in the same chamber also reduces process time.

While this invention has been described in terms of several embodiments, it will be appreciated that those skilled in the art upon reading the preceding specifications and studying the drawings will realize various alterations, additions, permutations and equivalents thereof. Therefore, it is intended that the present invention includes all such alterations, additions, permutations, and equivalents as fall within the true spirit and scope of the invention. In the claims, elements and/or steps do not imply any particular order of operation, unless explicitly stated in the claims.

What is claimed is:

1. A chamber for performing surface treatment and film deposition, comprising:
a first proximity head for substrate surface treatment configured to dispense a first treatment gas to treat a portion of a surface of a substrate under the first proximity head for substrate surface treatment; and
a first proximity head for atomic layer deposition (ALD) configured to sequentially dispensing a first reactant gas and a first purging gas to deposit a first ALD film under the second proximity head for ALD.

2. The apparatus of claim 1, further comprising:
a second proximity head for substrate surface treatment configured to dispense a second treatment gas to treat a portion of the surface of the substrate under the first proximity head for substrate surface treatment; and
a second proximity head for ALD configured to sequentially dispensing a second reactant gas and a second purging gas to deposit a second ALD film under the second proximity head for ALD.

3. The apparatus of claim 1, wherein the first proximity head for substrate surface treatment is used to perform a surface treatment before or after the substrate is deposited with the first ALD film.

4. The apparatus of claim 1, wherein the first ALD film is a barrier layer for copper.

5. The apparatus of claim 2, wherein the second ALD film is a liner layer for copper.

6. The apparatus of claim 2, wherein the second proximity head for substrate surface treatment is used to perform a surface treatment after the substrate is deposited with the second ALD film.

7. The apparatus of claim 2, wherein the first proximity head for ALD is placed next to the first proximity head for substrate surface treatment, the second proximity head for ALD being placed next to the first proximity head for ALD, and the second proximity head for substrate surface treatment being placed next to the second proximity head for ALD.

8. The apparatus for claim 7, wherein the first proximity head for substrate surface treatment is used to perform a pre-treatment before film deposition on the substrate, the first proximity head for ALD being used to deposit a barrier layer for copper, the second proximity head for ALD being used to deposit a liner layer for copper, and the second proximity head for substrate surface treatment being used to perform a post-treatment after the barrier layer and the liner layer being deposited.

9. The apparatus of claim 7, wherein the metals in the barrier layer and the liner layer are selected from the group consisting of tantalum (Ta), titanium (Ti), tungsten (W), zirconium (Zr), hafnium (Hf), molybdenum (Mo), niobium (Nb), vanadium (V), ruthenium (Ru) and chromium (Cr).

10. The apparatus of claim 1, wherein the chamber is configured to plasmarize the process gases in the chamber.

11. The apparatus of claim 1, wherein the surface treatment is performed to remove contaminants on the surface of the substrate or to activate the surface of the substrate for ALD barrier layer or liner layer deposition or for electroless copper seed layer deposition.

12. The apparatus of claim 1, wherein the first reactant gas is a barrier-metal-containing reactant or a reactant gas that form a barrier layer with the barrier-metal-containing reactant.

13. The apparatus of claim 2, wherein the second reactant gas is a liner-metal-containing reactant or a reactant gas that form a liner layer with the liner-metal-containing reactant.

14. A method of performing surface treatment and film deposition on a substrate in a processing chamber, comprising:
placing the substrate in the processing chamber with a plurality of proximity heads for surface treatment and film deposition, wherein each of the plurality of proximity head covers a portion of a substrate surface;
moving a pre-treatment proximity head above a region on the substrate surface;
performing a surface pre-treatment with the pre-treatment proximity head at the region on the substrate surface;
moving an atomic layer deposition 1 (ALD1) proximity head above the region on the substrate surface; and
depositing a barrier layer for copper with the ALD 1 proximity head at the region on the substrate surface.

15. The method of claim 12, further comprising:
moving an atomic layer deposition 2 (ALD2) proximity head above the region on the substrate surface;
depositing a liner layer for copper with the ALD2 proximity head at the region on the substrate surface;
moving a post-treatment proximity head above a region on the substrate surface; and
performing a surface post-treatment with the post-treatment proximity head at the region on the substrate surface.

16. The method of claim 15, wherein the plurality of proximity heads are placed in a sequence of the pre-treatment proximity head, the ALD1 proximity head, the ALD2 proximity head followed by the post-treatment proximity head.

17. The method of claim 14, wherein the surface pre-treatment is used to remove surface impurities prior to the deposition of the barrier layer or to increase initial deposition sites for the barrier layer deposited with ALD1 proximity head.

18. The method of claim 15, wherein the surface post-treatment is performed on the liner layer for copper to enhance nucleation for an electroless copper seed layer to be deposited.

19. The method of claim 15, wherein the metals in the barrier layer and the liner layer are selected from the group consisting of tantalum (Ta), titanium (Ti), tungsten (W), zirconium (Zr), hafnium (Hf), molybdenum (Mo), niobium (Nb), vanadium (V), ruthenium (Ru) and chromium (Cr).

20. The method of claim 14, wherein the process gas for surface treatment is plasmarized.

21. The method of clam 14, wherein at least one process gas of the ALD1 proximity head is plasmarized.

22. The method of claim 14, wherein the surface pre-treatment is performed to remove contaminants on the surface of the substrate or to activate the surface of the substrate for the barrier layer deposited with the ALD1 proximity head.

23. The method of claim 15, wherein the surface post-treatment is performed to remove contaminants on the surface of the substrate or to activate the surface of the substrate for the liner layer deposited with the ALD2 proximity head.

24. The method of claim 14, wherein the surface pre-treatment and the barrier layer deposition are performed in the same chamber to reduce process time and to protect the pre-treated substrate surface from being contaminated or being non-active before the barrier layer is deposited.
